(19) United States
(12) Patent Application Publication
(10) Pub. No.: US 2023/0275200 A1
(43) Pub. Date: Aug. 31, 2023

(54) DISPLAY DEVICE USING SEMICONDUCTOR LIGHT-EMITTING ELEMENT, AND METHOD FOR MANUFACTURING SAME

(71) Applicant: LG ELECTRONICS INC., Seoul (KR)

(72) Inventors: Dohyung LEE, Seoul (KR); Sangdae PARK, Seoul (KR); Hwankuk YUH, Seoul (KR); Jaegwang UM, Seoul (KR)

(73) Assignee: LG ELECTRONICS INC., Seoul (KR)

(21) Appl. No.: 18/016,220

(22) PCT Filed: Jul. 17, 2020
(86) PCT No.: PCT/KR2020/009443

§ 371 Date: Jan. 13, 2023

(51) Int. Cl. H01L 33/62; H01L 25/16; H01L 27/12

(52) U.S. Cl. CPC H01L 33/62; H01L 25/167; H01L 27/124; H01L 2933/0066

(57) ABSTRACT

Discussed is a display device that can include a base portion including a plurality of pixel areas, a plurality of semiconductor light-emitting elements disposed in the plurality of pixel areas, and a plurality of thin-film transistors disposed in the plurality of pixel areas and driving the plurality of semiconductor light-emitting elements. The plurality of pixel areas can include a first sub-pixel area in which a red semiconductor light-emitting element is dispose,; a second sub-pixel area in which a green semiconductor light-emitting element is disposed, a third sub-pixel area in which a blue semiconductor light-emitting element is disposed, and a fourth sub-pixel area in which any one of the red, green, and blue semiconductor light-emitting elements may be disposed. The thin-film transistors are respectively disposed in the first to fourth sub-pixel areas.

### TECHNICAL FIELD

The present disclosure relates to a display device using a semiconductor light-emitting element, particularly, a semiconductor light-emitting element having a size of several to several tens of µm, and a method for manufacturing the same.

### BACKGROUND ART

In recent years, liquid crystal displays (LCDs), organic light-emitting diode (OLED) displays, and micro-LED displays have been competed to implement a large-area display in the field of display technology.

Among them, a display using a semiconductor light-emitting element (micro-LED) having a diameter or cross-sectional area of 100 µm or less may provide very high efficiency because it does not absorb light using a polarizing plate or the like.

However, since millions of semiconductor light-emitting elements are required to implement a large area in the case of a micro-LED display, it has difficulty in transferring the devices compared to other technologies.

Technologies currently in development for transfer processes of micro-LEDs include pick & place, laser lift-off (LLO), self-assembly, or the like.

### DISCLOSURE OF INVENTION

### Technical Problem

An aspect of the present disclosure is to provide a display device configured with red, green and blue semiconductor light-emitting elements and a manufacturing method thereof.

In addition, another aspect of the present disclosure is to provide a high-resolution display device and a manufacturing method thereof.

### Solution to Problem

A display device according to the present disclosure may include a base portion including a plurality of pixel regions; a plurality of semiconductor light-emitting elements disposed in the pixel region; and a plurality of thin-film transistors disposed in the pixel region to drive the semiconductor light-emitting elements, wherein the pixel region includes a first sub-pixel region in which a red semiconductor light-emitting element is disposed, a second sub-pixel region in which a green semiconductor light-emitting element is disposed, a third sub-pixel region in which a blue semiconductor light-emitting element is disposed, and a fourth sub-pixel region in which any one of red, green and blue light-emitting elements can be disposed, and the thin-film transistors are disposed in the first to fourth sub-pixel regions, respectively.

In the present disclosure, the first to fourth sub-pixel regions may be arranged in a plurality of rows and columns in the pixel region.

In the present disclosure, the plurality of pixel regions may include a first pixel region including a fourth sub-pixel region in which the semiconductor light-emitting element is disposed; and a second pixel region including a fourth sub-pixel region in which the semiconductor light-emitting element is not disposed.

In the present disclosure, the display device may further include a wiring electrode disposed to pass through the pixel region, wherein the wiring electrode includes a gate electrode extending in a first direction; and a data electrode extending in a second direction crossing the first direction, and the gate electrode and the data electrode are electrically connected to the thin-film transistor.

In the present disclosure, the wiring electrode may include a Vss electrode disposed in parallel to the gate electrode, to which a ground voltage is applied; and a Vdd electrode disposed in parallel to the data electrode, to which a power supply voltage is applied, wherein the Vss electrode is electrically connected to the thin-film transistor, and the Vdd electrode is electrically connected to the semiconductor light-emitting element.

In the present disclosure, an electrical connection between the semiconductor light-emitting element and the Vdd electrode may be removed from any one of the first to third sub-pixel regions of the second pixel region.

A method of manufacturing a display device according to the present disclosure may include forming wiring electrodes and thin-film transistors on a base portion; disposing semiconductor light-emitting elements at preset positions on the base portion so as to be electrically connected to the wiring electrodes and the thin-film transistors; applying voltages to the wiring electrodes to check whether the semiconductor light-emitting element is defective; and performing repair according to a result of checking whether the semiconductor light-emitting element is defective, wherein the performing of the repair includes limiting the lighting of the semiconductor light-emitting element identified as defective, and disposing a new semiconductor light-emitting element that replaces the semiconductor light-emitting element identified as defective.

In the present disclosure, the performing of the repair may include disconnecting an electrical connection between the semiconductor light-emitting element identified as defective and the wiring electrode;

disposing the new semiconductor light-emitting element at a preset position of the base portion; and allocating driving information for the new semiconductor light-emitting element to the thin-film transistor.

In the present disclosure, the base portion may include a plurality of pixel regions,

wherein the pixel region includes a first sub-pixel region in which a red semiconductor light-emitting element is disposed, a second sub-pixel region in which a green semiconductor light-emitting element is disposed, a third sub-pixel region in which a blue semiconductor light-emitting element is disposed, and a fourth sub-pixel region in which any one of red, green and blue light-emitting elements can be disposed, and the thin-film transistors are disposed in the first to fourth sub-pixel regions, respectively.

In the present disclosure, the performing of the repair may be performed for each of the pixel regions, wherein the new semiconductor light-emitting element is disposed in the fourth sub-pixel region, and provided with a semiconductor light-emitting element emitting light of the same color as the semiconductor light-emitting element identified as defective in the pixel region.

In the present disclosure, the first to fourth sub-pixel regions may be arranged in a plurality of rows and columns in the pixel region.

In the present disclosure, the plurality of pixel regions may include a first pixel region including a fourth sub-pixel region in which the semiconductor light-emitting element is disposed; and a second pixel region including a fourth sub-pixel region in which the semiconductor light-emitting element is not disposed.

In the present disclosure, driving information for a semiconductor light-emitting element may not be allocated to a thin-film transistor disposed in the fourth sub-pixel region of the second pixel region.

### Advantageous Effects of Invention

According to the present disclosure, pixels may be designed in a quad structure to reduce an area occupied by a pixel region so as to decrease a gap between the pixels, thereby implementing high resolution.

In addition, according to the present disclosure, a number of semiconductor light-emitting elements redundantly transferred to a display panel may be decreased, thereby reducing manufacturing cost.

### BRIEF DESCRIPTION OF DRAWINGS

FIG. 1 is a conceptual view showing a display device using a semiconductor light-emitting element according to an embodiment of the present disclosure.

FIG. 2 is a partial enlarged view of portion “A” in the display device of FIG. 1, and FIGS. 3A and 3B are cross-sectional views taken along lines B-B and C-C in FIG. 2.

FIG. 4 is a conceptual view showing a flip-chip type semiconductor light-emitting element in FIG. 3.

FIGS. 5A through 5C are conceptual views showing various forms for implementing colors in connection with a flip-chip type semiconductor light-emitting element.

FIG. 6 is cross-sectional views showing a manufacturing method of a display device using a semiconductor light-emitting element according to the present disclosure.

FIG. 7 is a perspective view showing a display device using a semiconductor light-emitting element according to another embodiment of the present disclosure.

FIG. 8 is a cross-sectional view taken along line D-D in FIG. 7.

FIG. 9 is a conceptual view showing a vertical semiconductor light-emitting element in FIG. 8.

FIGS. 10 and 11 are views showing embodiments of a pixel region constituting a display device in the related art.

FIG. 12 is a view showing a pixel region (first pixel region) constituting a display device according to the present disclosure.

FIG. 13 is a view showing a pixel region (second pixel region) constituting the display device according to the present disclosure.

FIG. 14 is a circuit diagram of a pixel region constituting the pixel region according to FIGS. 12 and 13.

FIG. 15 is a view showing a pixel region of a display device in the related art and a pixel region of a display device according to the present disclosure.

FIG. 16 is a view showing a signal configuration of a display device in the related art and a signal configuration of a display device according to the present disclosure.

### MODE FOR THE INVENTION

Hereinafter, the embodiments disclosed herein will be described in detail with reference to the accompanying drawings, and the same or similar elements are designated with the same numeral references regardless of the numerals in the drawings and their redundant description will be omitted. A suffix “module” and “unit” used for constituent elements disclosed in the following description is merely intended for easy description of the specification, and the suffix itself does not give any special meaning or function. In describing the embodiments disclosed herein, moreover, the detailed description will be omitted when specific description for publicly known technologies to which the invention pertains is judged to obscure the gist of the present disclosure. Also, it should be noted that the accompanying drawings are merely illustrated to easily explain the concept of the invention, and therefore, they should not be construed to limit the technological concept disclosed herein by the accompanying drawings. Furthermore, it will be understood that when an element such as a layer, region or substrate is referred to as being “on” another element, it can be directly on the other element or an intermediate element may also be interposed therebetween.

A display device disclosed herein may include a mobile phone, a smart phone, a laptop computer, a digital broadcast terminal, a personal digital assistant (PDA), a portable multimedia player (PMP), a navigation, a slate PC, a tablet PC, an ultrabook, a digital TV, a desktop computer, and the like. However, even if a new product type to be developed later includes a display, a configuration according to an embodiment disclosed herein may be applicable thereto.

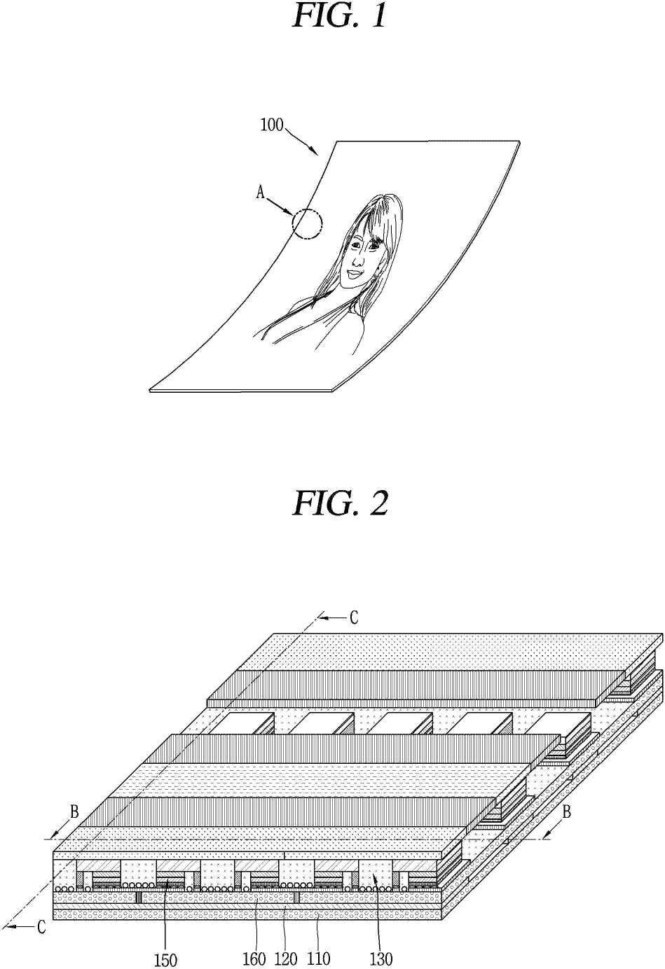

FIG. 1 is a conceptual view showing a display device using a semiconductor light-emitting element according to an embodiment of the present disclosure.

According to the drawing, information processed in the controller of the display device 100 may be displayed on a flexible display. The flexible display may include a flexible, bendable, twistable, foldable and rollable display. For example, the flexible display may be a display manufactured on a thin and flexible substrate that can be warped, bent, folded or rolled like a paper sheet while maintaining the display characteristics of a flat display in the related art.

A display region of the flexible display becomes a plane in a configuration that the flexible display is not warped (e.g., a configuration having an infinite radius of curvature, hereinafter, referred to as a “first configuration”). The display region thereof becomes a curved surface in a configuration that the flexible display is warped by an external force in the first configuration (e.g., a configuration having a finite radius of curvature, hereinafter, referred to as a “second configuration”). As illustrated, information displayed in the second configuration may be visual information displayed on a curved surface. The visual information may be implemented by individually controlling the light emission of sub-pixels disposed in a matrix form. The sub-pixel denotes a minimum unit for implementing one color.

The sub-pixel of the flexible display may be implemented by a semiconductor light-emitting element. According to the present disclosure, a light-emitting diode (LED) is illustrated as a type of semiconductor light-emitting element. The light-emitting diode may be formed with a small size to perform the role of a sub-pixel even in the second configuration through this.

Hereinafter, a flexible display implemented using the light-emitting diode will be described in more detail with reference to the accompanying drawings.

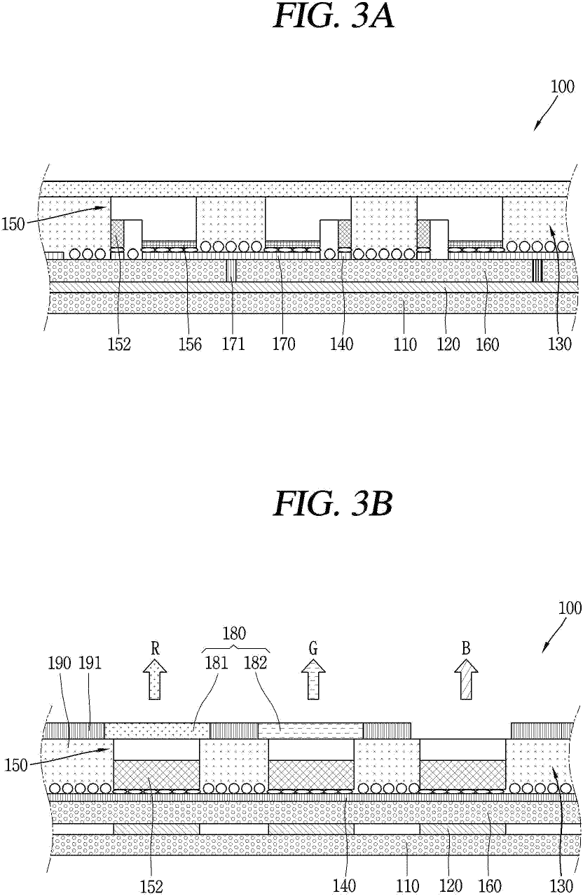

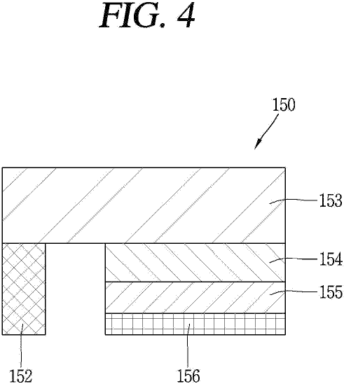

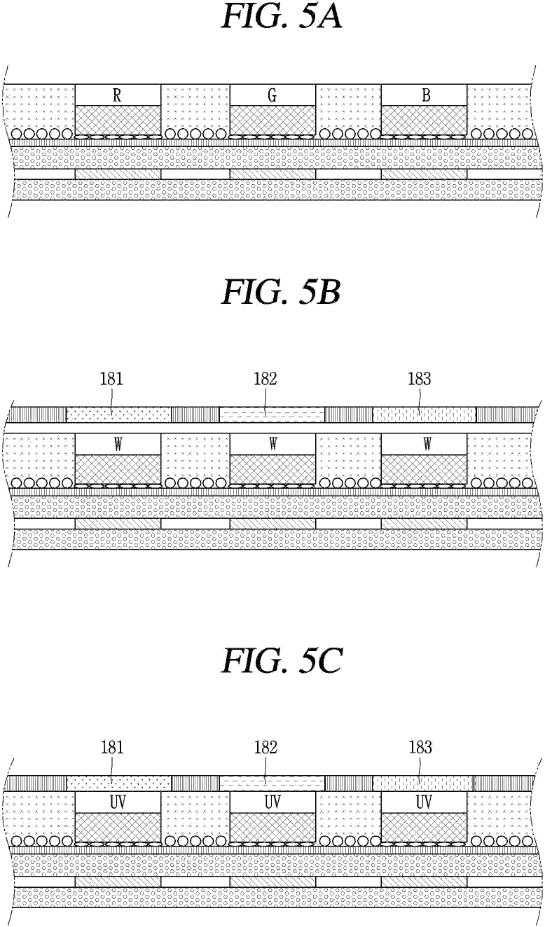

FIG. 2 is a partial enlarged view of portion “A” in FIG. 1, and FIGS. 3A and 3B are cross-sectional views taken along lines B-B and C-C in FIG. 2, FIG. 4 is a conceptual view showing a flip-chip type semiconductor light-emitting element in FIG. 3A, and FIGS. 5A to 5C are conceptual views showing various forms for implementing colors in connection with a flip-chip type semiconductor light-emitting element.

FIGS. 2, 3A and 3B illustrate a display device 100 using a passive matrix (PM) type semiconductor light-emitting element as a display device 100 using a semiconductor light-emitting element. However, an example described below may also be applicable to an active-matrix (AM) type semiconductor light-emitting element.

The display device 100 may include a substrate 110, a first electrode 120, a conductive adhesive layer 130, a second electrode 140, and a plurality of semiconductor light-emitting elements 150.

The substrate 110 may be a flexible substrate. The substrate 110 may include glass or polyimide (PI) to implement flexible performance. In addition, an insulating and flexible material such as polyethylene naphthalate (PEN) or polyethylene terephthalate (PET) may be used as a component of the substrate 110. Furthermore, the substrate 110 may be either one of transparent and non-transparent materials.

The substrate 110 may be a wiring substrate disposed with the first electrode 120, and the first electrode 120 may be placed on the substrate 110.

According to the drawing, an insulating layer 160 may be deposited and formed on the substrate 110 placed with the first electrode 120, and an auxiliary electrode 170 may be disposed on the insulating layer 160. In this case, a configuration in which the insulating layer 160 is deposited on the substrate 110 may be a single wiring substrate. More specifically, the insulating layer 160 may be incorporated into the substrate 110 with an insulating and flexible material such as polyimide (PI), PEN, PET or the like to form a single wiring substrate.

The auxiliary electrode 170 as an electrode for electrically connecting the first electrode 120 to the semiconductor light-emitting element 150 is placed on the insulating layer 160, and disposed to correspond to the position of the first electrode 120. For example, the auxiliary electrode 170 has a dot shape, and may be electrically connected to the first electrode 120 by means of an electrode hole 171 passing through the insulating layer 160. The electrode hole 171 may be formed by filling into a conductive material into a via hole.

According to the accompanying drawings, the conductive adhesive layer 130 may be formed on one surface of the insulating layer 160, but the present disclosure may not be necessarily limited to this. For example, a layer performing a specific function may be formed between the insulating layer 160 and the conductive adhesive layer 130, and a structure in which the conductive adhesive layer 130 is disposed on a substrate without the insulating layer 160 is also allowed. The conductive adhesive layer 130 may serve as an insulating layer in the structure in which the conductive adhesive layer 130 is disposed on the substrate.

The conductive adhesive layer 130 may be a layer having adhesiveness and conductivity, and to this end, a conductive material and an adhesive material may be mixed and formed in the conductive adhesive layer 130. Furthermore, the conductive adhesive layer 130 may have flexibility, thereby allowing a flexible function in the display device.

For an example, the conductive adhesive layer 130 may be an anisotropic conductive film (ACF), an anisotropic conductive paste, a solution containing conductive particles, and the like. The conductive adhesive layer 130 may allow electrical interconnection in the z-direction passing through a thickness thereof, but may be configured as an electrical insulating layer in the horizontal x-y direction. Accordingly, the conductive adhesive layer 130 may be referred to as a z-axis conductive layer (however, hereinafter referred to as a “conductive adhesive layer”).

The anisotropic conductive film is a film with a form in which an anisotropic conductive medium is mixed with an insulating base member, and thus when heat and pressure are applied thereto, only a specific portion thereof may have conductivity by means of the anisotropic conductive medium. Herein, it is described that heat and pressure are applied to the anisotropic conductive film, but another method (e.g., only either one of heat and pressure is applied or a UV curing method) may be used to allow the anisotropic conductive film to have partial conductivity.

Furthermore, the anisotropic conductive medium may be conductive balls or conductive particles. According to the drawing, the anisotropic conductive film is a film in which conductive balls are mixed with an insulating base member, and when heat and pressure are applied, only a specific portion thereof has conductivity by the conductive balls. The anisotropic conductive film may be in a state in which a core with a conductive material contains a plurality of particles coated by an insulating layer with a polymer material, and in this case, it may have conductivity by means of the core while breaking an insulating layer of particles contained in a portion to which heat and pressure are applied. Here, the shape of the core may be deformed to form a layer in contact with each other in a thickness direction of the film. More specifically, heat and pressure may be applied to the anisotropic conductive film as a whole, and an electrical connection in the z-axis direction may be partially formed by a height difference of a counterpart adhered by the anisotropic conductive film.

For another example, the anisotropic conductive film may be in a state in which an insulating core contains a plurality of particles coated with a conductive material. In this case, the conductive material in the portion to which heat and pressure is applied is deformed (stuck) to have conductivity in the thickness direction of the film. For another example, a form in which the conductive material passed through the insulating base member in the z-axis direction to have conductivity in the thickness direction of the film may also be allowed, and in this case, the conductive material may have a pointed end.

According to the drawing, the anisotropic conductive film may be a fixed array anisotropic conductive film (ACF) configured with a form in which conductive balls are inserted into one surface of the insulating base member. The insulating base member is formed of a material having an adhesive property, and the conductive balls are intensively disposed at a bottom portion of the insulating base member, and is deformed together with the conductive balls to have conductivity in a vertical direction when heat and pressure are applied from the base member.

However, the present disclosure may not be necessarily limited to this, and the anisotropic conductive film may be all allowed to have a form in which conductive balls are randomly mixed with an insulating base member or a form configured with a plurality of layers in which conductive balls are disposed at any one layer (double-ACF), and the like.

The anisotropic conductive paste as a form coupled to a paste and conductive balls may be a paste in which conductive balls are mixed with an insulating and adhesive base material. Furthermore, a solution containing conductive particles may be a solution in a form containing conductive particles or nano particles.

Referring to the accompanying drawings, the second electrode 140 is located at the insulating layer 160 to be separated from the auxiliary electrode 170. In other words, the conductive adhesive layer 130 is disposed on the insulating layer 160 located with the auxiliary electrode 170 and second electrode 140.

When the conductive adhesive layer 130 is formed on the insulating layer 160 in a state that the auxiliary electrode 170 and second electrode 140 are located, and then the semiconductor light-emitting element 150 is connected thereto in a flip chip form with the application of heat and pressure, the semiconductor light-emitting element 150 is electrically connected to the first electrode 120 and second electrode 140.

The semiconductor light-emitting element 150 may be a flip chip type light-emitting element as shown in FIG. 4.

For example, the semiconductor light-emitting element 150 may include a p-type electrode 156, a p-type semiconductor layer 155 formed with the p-type electrode 156, an active layer 154 formed on the p-type semiconductor layer 155, an n-type semiconductor layer 153 formed on the active layer 154, and an n-type electrode 152 disposed to be separated from the p-type electrode 156 in a horizontal direction on the n-type semiconductor layer 153. In this case, the p-type electrode 156 may be electrically connected to the auxiliary electrode 170 by the conductive adhesive layer 130, and the n-type electrode 152 may be electrically connected to the second electrode 140.

Referring to FIGS. 2, 3A and 3B, the auxiliary electrode 170 may be formed in an elongated manner in one direction so that one auxiliary electrode 170 may be electrically connected to the plurality of semiconductor light-emitting elements 150. For example, the p-type electrodes 156 of the semiconductor light-emitting elements 150 on the left and right with respect to the auxiliary electrode 170 may be electrically connected to one auxiliary electrode.

More specifically, the semiconductor light-emitting element 150 is pressed into the conductive adhesive layer 130, and through this, only a portion between the p-type electrode 156 and auxiliary electrode 170 of the semiconductor light-emitting element 150 and a portion between the n-type electrode 152 and second electrode 140 of the semiconductor light-emitting element 150 have conductivity, and the remaining portion does not have conductivity since there is no push-down of the semiconductor light-emitting element 150. As described above, the conductive adhesive layer 130 may form an electrical connection as well as allow a mutual coupling between the semiconductor light-emitting element 150 and the auxiliary electrode 170 and between the semiconductor light-emitting element 150 and the second electrode 140.

Furthermore, a plurality of semiconductor light-emitting elements 150 constitute a light-emitting array, and a phosphor layer 180 is formed on the light-emitting array.

The light-emitting element array may include a plurality of semiconductor light-emitting elements 150 with different self-luminance values. Each of the semiconductor light-emitting elements 150 constitutes a sub-pixel, and is electrically connected to the first electrode 120. For example, there may exist a plurality of first electrodes 120, and the semiconductor light-emitting elements 150 are arranged in several rows, and each row of the semiconductor light-emitting elements 150 may be electrically connected to any one of the plurality of first electrodes.

Furthermore, the semiconductor light-emitting elements 150 may be connected in a flip chip form, and thus semiconductor light-emitting elements 150 grown on a transparent dielectric substrate. The semiconductor light-emitting elements 150 may be, for example, nitride semiconductor light-emitting elements. The semiconductor light-emitting element 150 has an excellent luminance characteristic, and thus it may be possible to configure individual sub-pixels even with a small size thereof.

Referring to the drawings, a partition wall 190 may be formed between the semiconductor light-emitting elements 150. In this case, the partition wall 190 may perform the role of dividing individual sub-pixels from one another, and be formed as an integral body with the conductive adhesive layer 130. For example, a base member of the anisotropic conductive film may form the partition wall 190 by inserting the semiconductor light-emitting element 150 into the anisotropic conductive film.

Furthermore, when the base member of the anisotropic conductive film is black, the partition wall 190 may have reflective characteristics while at the same time increasing contrast with no additional black insulator.

For another example, a reflective partition wall may be separately provided with the partition wall 190. In this case, the partition wall 190 may include a black or white insulator according to the purpose of the display device. When the partition wall 190 of a white insulator is used, an effect of enhancing reflectivity may be obtained. When a partition wall of a black insulator is used, a contrast ratio may be increased while having a reflection characteristic.

The phosphor layer 180 may be located at an outer surface of the semiconductor light-emitting element 150. For example, when the semiconductor light-emitting element 150 is a blue semiconductor light-emitting element that emits blue (B) light, and the phosphor layer 180 may perform the role of converting the blue (B) light into the color of a sub-pixel. The phosphor layer 180 may be a red phosphor layer 181 or green phosphor layer 182 constituting individual pixels.

In other words, a red phosphor 181 capable of converting blue (B) light into red (R) light may be deposited on the blue semiconductor light-emitting element 151 at a position implementing a red sub-pixel, and a green phosphor 182 capable of converting blue (B) light into green (G) light may be deposited on the blue semiconductor light-emitting element 151 at a position implementing a green sub-pixel. Furthermore, only the blue semiconductor light-emitting element 151 may be solely used at a position implementing a blue sub-pixel. In this case, the red (R), green (G) and blue (B) sub-pixels may implement one pixel. Specifically, the phosphor 180 of one color may be deposited along each line of the first electrode 120, and thus, one line in the first electrode 120 may be an electrode that controls one color. In other words, red (R), green (B) and blue (B) may be sequentially disposed along the second electrode 140, thereby implementing sub-pixels.

However, the present disclosure may not be necessarily limited to this, and the semiconductor light-emitting element 150 may be combined with a quantum dot (QD) instead of the phosphor 180 to implement sub-pixels such as red (R), green (G) and blue (B).

In addition, a black matrix 191 may be disposed between the respective phosphor layers 180 to enhance contrast.

However, the present disclosure may not be necessarily limited to this, and another structure for implementing blue, red and green may be also applicable thereto.

Referring to FIG. 5A, each of the semiconductor light-emitting elements 150 may be implemented with a high-power light-emitting element that emits light of various colors including blue in which gallium nitride (GaN) is mostly used, and indium (In) and or aluminum (Al) are added thereto.

In this case, the semiconductor light-emitting element 150 may be provided with red, green and blue semiconductor light-emitting elements, respectively, to implement each sub-pixel. For example, red, green and blue semiconductor light-emitting elements (R, G, B) are alternately disposed, and red, green and blue sub-pixels implement one pixel by means of the red, green and blue semiconductor light-emitting elements, thereby implementing a full color display.

Referring to FIG. 5B, the semiconductor light-emitting element may be a white light-emitting element (W) provided with a yellow phosphor layer for each element. In this case, a red phosphor layer 181, a green phosphor layer 182 and a blue phosphor layer 183 may be provided on the white light-emitting element (W) to implement a sub-pixel. Furthermore, a color filter repeated with red, green and blue on the white light-emitting element (W) may be used to implement a sub-pixel.

Referring to FIG. 5C, a red phosphor layer 181, a green phosphor layer 182 and blue phosphor layer 183 may be provided on a ultra violet light-emitting element (UV). As such, the semiconductor light-emitting element 150 may be used over an entire region up to ultra violet as well as visible light, and may be extended to a form of semiconductor light-emitting element in which ultra violet UV can be used as an excitation source.

Taking the present example into consideration again, the semiconductor light-emitting element 150 is placed on the conductive adhesive layer 130 to configure a sub-pixel in the display device. The semiconductor light-emitting element 150 has an excellent luminance characteristic, and thus it may be possible to configure individual sub-pixels even with a small size thereof. A size of an individual semiconductor light-emitting element 150 may be a rectangular or square device having a side length of 80 µm or less. In the case of a rectangular shaped element, the size thereof may be less than 20 × 80 µm.

Furthermore, even when a square shaped semiconductor light-emitting element 150 with a length of side of 10 µm is used for a sub-pixel, it will exhibit sufficient brightness for implementing a display device. Accordingly, for example, in the case of a rectangular pixel in which one side of a sub-pixel is 600 µm in size, and the remaining one side thereof is 300 µm, a relative distance between the semiconductor light-emitting elements becomes sufficiently large, thereby implementing a flexible display device of a HD quality

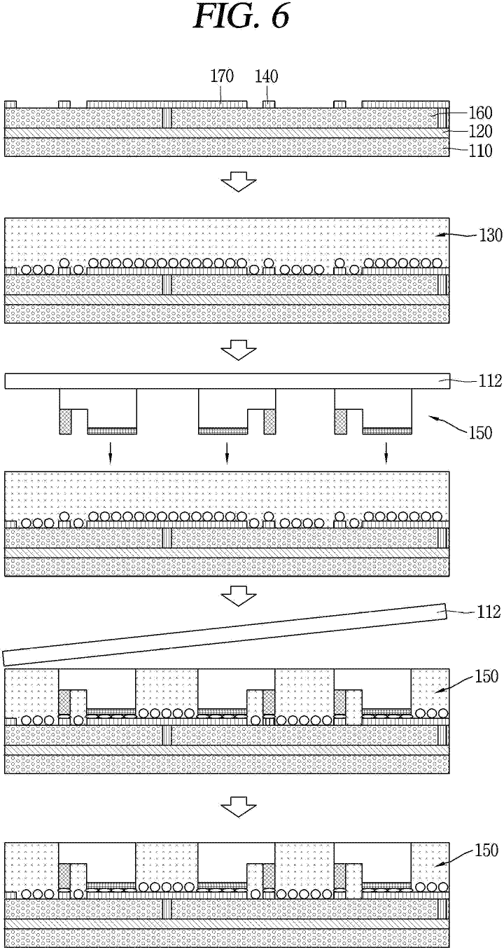

The display device using the semiconductor light-emitting element described above may be manufactured by a new type of manufacturing method, and hereinafter, the manufacturing method will be described with reference to FIG. 6.

Referring to FIG. 6, first, the conductive adhesive layer 130 is formed on the insulating layer 160 located with the auxiliary electrode 170 and second electrode 140. The insulating layer 160 is deposited on the first substrate 110 to form one substrate (or wiring substrate), and the first electrode 120, auxiliary electrode 170 and second electrode 140 are disposed at the wiring substrate. The first electrode 120 and second electrode 150 may be disposed in a perpendicular direction to each other. Furthermore, the first substrate 110 and insulating layer 160 may contain glass or polyimide (PI), respectively, to implement a flexible display device.

The conductive adhesive layer 130 may be implemented by an anisotropic conductive film, and to this end, an anisotropic conductive film may be coated on a substrate located with the insulating layer 160.

Next, a second substrate 112 located with a plurality of semiconductor light-emitting elements 150 corresponding to the position of the auxiliary electrodes 170 and second electrodes 140 and constituting individual pixels is disposed such that the semiconductor light-emitting element 150 faces the auxiliary electrode 170 and second electrode 140.

In this case, the second substrate 112 as a growth substrate for growing the semiconductor light-emitting element 150 may be a sapphire substrate or silicon substrate.

The semiconductor light-emitting element 150 may have a gap and size capable of implementing a display device when formed in the unit of wafer, and thus effectively used for a display device.

Next, the wiring substrate is thermally compressed to the second substrate 112. For example, the wiring substrate and second substrate 112 may be thermally compressed to each other by applying an ACF press head. The wiring substrate and second substrate 112 are bonded to each other using the thermal compression. Only a portion between the semiconductor light-emitting element 150 and the auxiliary electrode 170 and second electrode 140 may have conductivity due to the characteristics of an anisotropic conductive film having conductivity by thermal compression, thereby allowing the electrodes and semiconductor light-emitting element 150 to be electrically connected to each other. At this time, the semiconductor light-emitting element 150 may be inserted into the anisotropic conductive film, thereby forming a partition wall between the semiconductor light-emitting elements 150.

Next, the second substrate 112 is removed. For example, the second substrate 112 may be removed using a laser lift-off (LLO) or chemical lift-off (CLO) method.

Finally, the second substrate 112 is removed to expose the semiconductor light-emitting elements 150 to the outside. Silicon oxide (SiOx) or the like may be coated on the wiring substrate coupled to the semiconductor light-emitting element 150 to form a transparent insulating layer (not shown).

Furthermore, it may further include the process of forming a phosphor layer on one surface of the semiconductor light-emitting element 150. For example, the semiconductor light-emitting element 150 may be a blue semiconductor light-emitting element for emitting blue (B) light, and red or green phosphor for converting the blue (B) light into the color of the sub-pixel may form a layer on one surface of the blue semiconductor light-emitting element.

The manufacturing method or structure of a display device using the foregoing semiconductor light-emitting element may be modified and implemented in various forms. For such an example, the foregoing display device may be applicable to a vertical semiconductor light-emitting element. Hereinafter, the vertical structure will be described with reference to FIGS. 5 and 6.

Furthermore, according to the following modified example or embodiment, the same or similar reference numerals are designated to the same or similar configurations to the foregoing example, and the description thereof will be substituted by the earlier description.

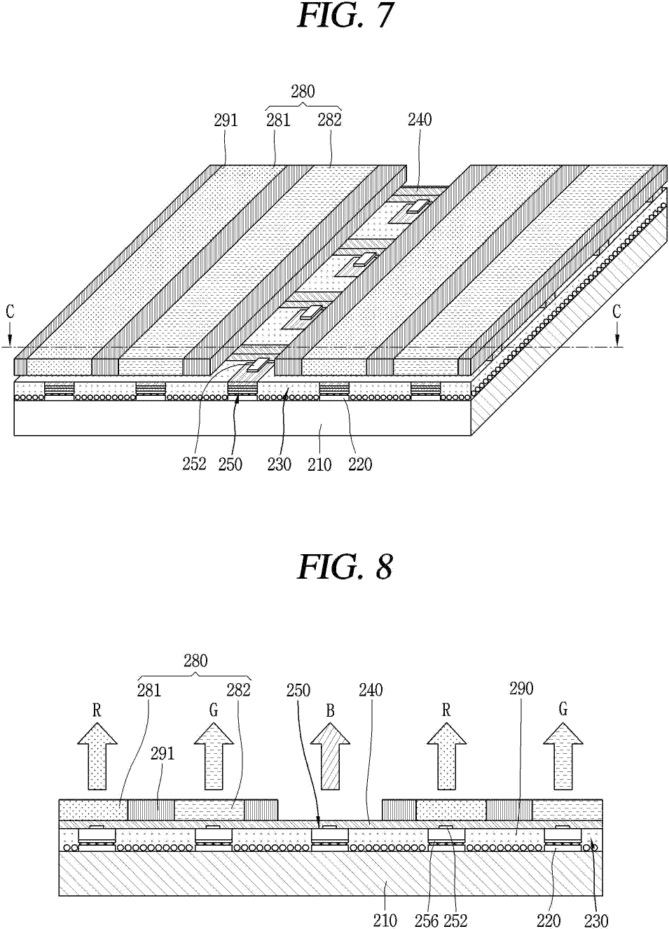

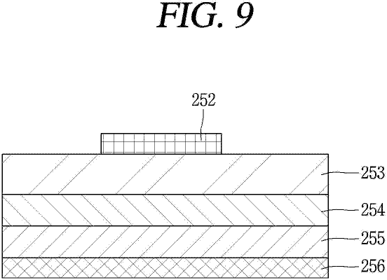

FIG. 7 is a perspective view showing a display device using a semiconductor light-emitting element according to another embodiment of the present disclosure, FIG. 8 is a cross-sectional view taken along line C-C in FIG. 7, and FIG. 9 is a conceptual view showing a vertical type semiconductor light-emitting element in FIG. 8.

According to the drawings, the display device may be display device using a passive matrix (PM) type of vertical semiconductor light-emitting element.

The display device may include a substrate 210, a first electrode 220, a conductive adhesive layer 230, a second electrode 240, and a plurality of semiconductor light-emitting elements 250.

The substrate 210, which is a wiring board on which the first electrode 220 is disposed, may include polyimide (PI) to implement a flexible display device, in addition, any insulating and flexible material may be used therefor.

The first electrode 220 may be located on the substrate 210, and formed with a bar-shaped electrode elongated in one direction. The first electrode 220 may perform the role of a data electrode.

The conductive adhesive layer 230 is formed on the substrate 210 located with the first electrode 220. Similarly to a display device to which a flip chip type light-emitting element is applied, the conductive adhesive layer 230 may be an anisotropic conductive film (ACF), an anisotropic conductive paste, a solution containing conductive particles, and the like. However, the present embodiment illustrates a case where the conductive adhesive layer 230 is implemented by an anisotropic conductive film.

When an anisotropic conductive film is located in a state that the first electrode 220 is located on the substrate 210, and then heat and pressure are applied to connect the semiconductor light-emitting element 250 thereto, the semiconductor light-emitting element 250 is electrically connected to the first electrode 220. At this time, the semiconductor light-emitting element 250 may be preferably disposed on the first electrode 220.

The electrical connection is generated because an anisotropic conductive film partially has conductivity in the thickness direction when heat and pressure are applied as described above. Accordingly, the anisotropic conductive film is partitioned into a portion 231 having conductivity and a portion 232 having no conductivity in the thickness direction thereof.

Furthermore, the anisotropic conductive film contains an adhesive component, and thus the conductive adhesive layer 230 implements a mechanical coupling as well as an electrical coupling between the semiconductor light-emitting element 250 and the first electrode 220.

As such, the semiconductor light-emitting element 150 is positioned on the conductive adhesive layer 130, thereby constituting a sub-pixel in the display device. The semiconductor light-emitting element 150 has an excellent luminance characteristic, and thus it may be possible to configure individual sub-pixels even with a small size thereof. A size of an individual semiconductor light-emitting element 150 may be a rectangular or square device having a side length of 80 µm or less. In the case of a rectangular shaped element, the size thereof may be less than 20 × 80 µm.

The semiconductor light-emitting element 250 may be a vertical structure.

A plurality of second electrodes 240 disposed in a direction of crossing the length direction of the first electrode 220, and electrically connected to the vertical semiconductor light-emitting element 250, respectively, may be located between vertical semiconductor light-emitting elements.

Referring to FIG. 9, the vertical semiconductor light-emitting element may include a p-type electrode 256, a p-type semiconductor layer 255 formed with the p-type electrode 256, an active layer 254 formed on the p-type semiconductor layer 255, an n-type semiconductor layer 253 formed on the active layer 254, and an n-type electrode 252 formed on an n-type semiconductor layer 253. In this case, the p-type electrode 256 located at the bottom thereof may be electrically connected to the first electrode 220 by the adhesive layer 230, and the n-type electrode 252 located at the top thereof may be electrically connected to the second electrode 240 which will be described later. The electrodes may be disposed in the upward/downward direction in the vertical semiconductor light-emitting element 250, thereby providing a great advantage capable of reducing the chip size.

Referring to FIG. 8, a phosphor layer 280 may be formed on one surface of the semiconductor light-emitting element 250. For example, the semiconductor light-emitting element 250 is a blue semiconductor light-emitting element 251 that emits blue (B) light, and the phosphor layer 280 for converting the blue (B) light into the color of the sub-pixel may be provided thereon. In this case, the phosphor layer 280 may be a red phosphor 281 and a green phosphor 282 constituting individual pixels.

In other words, a red phosphor 281 capable of converting blue light into red (R) light may be deposited on the blue semiconductor light-emitting element 251 at a position implementing a red sub-pixel, and a green phosphor 282 capable of converting blue light into green (G) light may be deposited on the blue semiconductor light-emitting element 251 at a position implementing a green sub-pixel. Furthermore, only the blue semiconductor light-emitting element 251 may be solely used at a position implementing a blue sub-pixel. In this case, the red (R), green (G) and blue (B) sub-pixels may implement one pixel.

However, the present disclosure may not be necessarily limited to this, and another structure for implementing blue, red and green may be also applicable thereto as described above in a display device to which a flip chip type light-emitting element is applied.

Taking the present embodiment into consideration, the second electrode 240 is located between the semiconductor light-emitting elements 250, and electrically connected to the semiconductor light-emitting elements 250. For example, the semiconductor light-emitting elements 250 may be disposed in a plurality of rows, and the second electrode 240 may be located between the rows of the semiconductor light-emitting elements 250.

Since a distance between the semiconductor light-emitting elements 250 constituting individual pixels is sufficiently large, the second electrode 240 may be located between the semiconductor light-emitting elements 250.

The second electrode 240 may be formed with a bar-shaped electrode elongated in one direction, and disposed in a perpendicular direction to the first electrode.

Furthermore, the second electrode 240 may be electrically connected to the semiconductor light-emitting element 250 by an electrode protruded from the second electrode 240. Specifically, the connecting electrode may be an n-type electrode 252 of the semiconductor light-emitting element 250. For example, the n-type conductive electrode 252 is formed with an ohmic electrode for ohmic contact, and the second electrode 240 covers at least part of the ohmic electrode by printing or deposition. Through this, the second electrode 240 may be electrically connected to the n-type electrode 252 of the semiconductor light-emitting element 250.

As illustrated, the second electrode 240 may be located on the conductive adhesive layer 230, and if necessary, a transparent insulating layer (not shown) including silicon oxide (SiOx) may be formed on the substrate 210 on which the semiconductor light-emitting element 250 is formed. When the transparent insulating layer is formed and then the second electrode 240 is placed thereon, the second electrode 240 may be located on the transparent insulating layer. Furthermore, the second electrode 240 may be formed to be separated from the conductive adhesive layer 230 or transparent insulating layer.

When a transparent electrode such as indium tin oxide (ITO) is used to locate the second electrode 240 on the semiconductor light-emitting element 250, the ITO material has a problem of bad adhesiveness with the n-type semiconductor 253. Accordingly, the second electrode 240 may be placed between the semiconductor light-emitting elements 250, thereby obtaining an advantage in which the transparent electrode is not required. Accordingly, an n-type semiconductor layer 253 and a conductive material having a good adhesiveness may be used as a horizontal electrode without being restricted by the selection of a transparent material, thereby enhancing the light extraction efficiency.

According to the drawing, a partition wall 290 may be located between the semiconductor light-emitting elements 250. The partition wall 290 may be disposed between the vertical semiconductor light-emitting elements 250 to isolate the semiconductor light-emitting element 250 constituting individual pixels. In this case, the partition wall 290 may perform the role of dividing individual sub-pixels from one another, and be formed as an integral body with the conductive adhesive layer 230. For example, a base member of the anisotropic conductive film may form the partition wall 290 by inserting the semiconductor light-emitting element 250 into the anisotropic conductive film.

Furthermore, when the base member of the anisotropic conductive film is black, the partition wall 290 may have reflective characteristics while at the same time increasing contrast with no additional black insulator.

For another example, a reflective partition wall may be separately provided with the partition wall 290. The partition wall 290 may include a black or white insulator according to the purpose of the display device.

If the second electrode 240 is precisely located on the conductive adhesive layer 230 between the semiconductor light-emitting elements 250, the partition wall 290 may be located between the vertical semiconductor light-emitting elements 250 and the second electrodes 240. Accordingly, individual sub-pixels may be configured even with a small size using the semiconductor light-emitting element 250, and a distance between the semiconductor light-emitting elements 250 may be relatively sufficiently large to place the second electrode 240 between the semiconductor light-emitting elements 250, thereby having the effect capable of implementing a flexible display device of a HD image quality.

In addition, a black matrix 291 may be disposed between the respective phosphor layers to enhance contrast.

As described above, the semiconductor light-emitting element 250 is positioned on the conductive adhesive layer 230, thereby constituting an individual pixel in the display device. The semiconductor light-emitting element 250 has an excellent luminance characteristic, and thus it may be possible to configure individual sub-pixels even with a small size thereof. As a result, a full color display in which the sub-pixels of red (R), green (G) and blue (B) constitute one pixel may be implemented by means of the semiconductor light-emitting elements 250.

Meanwhile, a display device using the above-described semiconductor light-emitting element may be implemented in a passive matrix (PM) method or an active matrix (AM) method.

The present disclosure relates to a display device using a semiconductor light-emitting element and a method for manufacturing the same, and more particularly, discloses a display device driven by an active-matrix method and a method for manufacturing the same.

As illustrated in FIG. 4, the display device according to the present disclosure may be configured with flip-chip type red, green and blue semiconductor light-emitting elements. However, the present disclosure may not be limited thereto, and may also applied to an embodiment configured with vertical red, green, and blue semiconductor light-emitting elements.

Hereinafter, embodiments of a display device and a manufacturing method thereof according to the present disclosure will be described in detail.

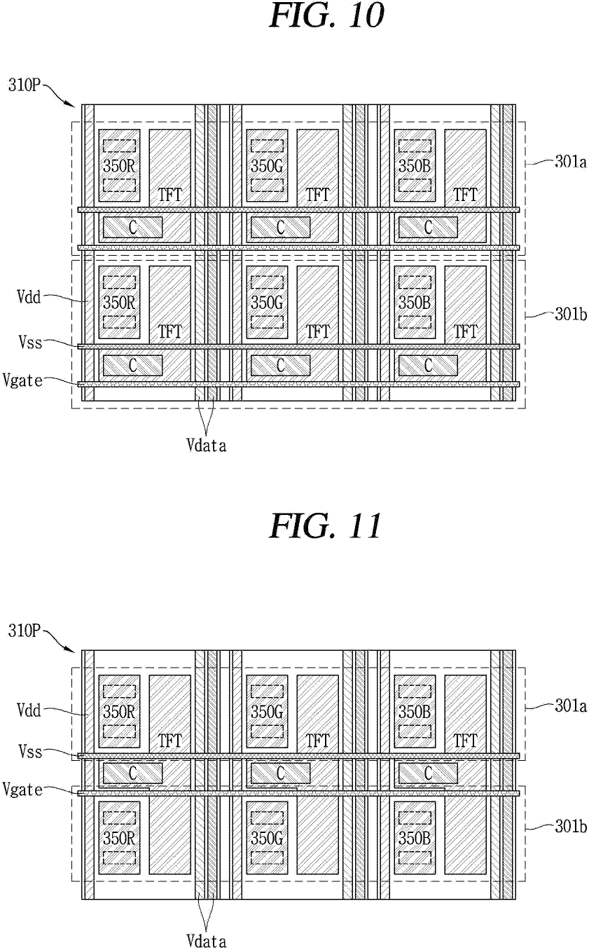

First, with reference to FIGS. 10 and 11, the structure and problems of a display device driven by an active-matrix method (hereinafter, a display device) will be described.

FIGS. 10 and 11 are views showing embodiments of a pixel region constituting a display device in the related art.

The display device in the related art may include a semiconductor light-emitting element emitting red light (hereinafter, referred to as a red semiconductor light-emitting element), a semiconductor light-emitting element emitting green light (hereinafter, referred to as a green semiconductor light-emitting element), and a semiconductor light-emitting element emitting blue light (hereinafter, referred to as a blue semiconductor light-emitting element), and the pixels of the display device may be configured with the semiconductor light-emitting elements.

Specifically, referring to FIGS. 10 and 11, a red semiconductor light-emitting element 350R, a green semiconductor light-emitting element 350G, and a blue semiconductor light-emitting element 350B may be arranged side by side in a pixel region 310P of the display device to constitute individual pixels (sub-pixel line 301a). Furthermore, the pixel region 310P may include the red semiconductor light-emitting element 350R, the green semiconductor light-emitting element 350G, and the blue semiconductor light-emitting element 350B, which are redundantly arranged side by side like the individual pixels (redundancy line 301b). That is, the display device in the related art has redundancy for individual pixels, and thus the pixel region 310P is configured with a total of 6 semiconductor light-emitting elements.

Furthermore, the pixel region 310P may include thin-film transistors (TFTs) for driving semiconductor light-emitting elements. For example, the thin-film transistor TFT may be provided for each semiconductor light-emitting element as shown in FIG. 10 (one-to-one matching) or for each semiconductor light-emitting element emitting light of the same color as shown in FIG. 11 (two-to-one matching). That is, in the display device in the related art, one thin-film transistor (TFT) has been configured to match an individual semiconductor light-emitting element or to match a semiconductor light-emitting element emitting light of the same color.

The above-described pixel region 310P of the display device in the related art has been provided with three semiconductor light-emitting elements disposed on the sub-pixel line 301a to constitute an individual pixel and three redundant semiconductor light-emitting elements disposed on the redundancy line 301b, and thin-film transistors (TFTs) connected thereto.

However, there is a problem in that the pixel region 310P occupies a large area in a structure including redundant semiconductor light-emitting elements for each individual pixel regardless of whether the semiconductor light-emitting elements constituting the individual pixel are defective. In particular, due to a space occupied by semiconductor light-emitting elements that are not actually used for the driving of display device, it has been difficult to a decrease a distance between pixels, and thus there has been a limitation in implementing a high-resolution display device.

The present disclosure has solved the above problems, and provides a high-resolution display device configured with red, green and blue semiconductor light-emitting elements and a manufacturing method thereof. In particular, according to the present disclosure, in order to implement a narrow spacing between pixels, a pixel region has been configured differently from that of the display device in the related art.

Prior to describing a display device according to the present disclosure, the basic structure of an active matrix driving type display device will be described.

The active matrix driving type display device may control the driving (lighting) of a semiconductor light-emitting element using a thin-film transistor (TFT). In detail, two types of thin-film transistors (a switching TFT and a driving TFT) may be provided to control the driving of one semiconductor light-emitting element.

Furthermore, four types of wire electrodes Vss, Vdd, Vgate, Vdata to which voltage signals for driving the semiconductor light-emitting element are applied may be disposed on a substrate (or base portion). Referring to the accompanying drawings, either one of the conductive electrodes 1051, 1052 of the semiconductor light-emitting element 1050 may be connected to the Vdd electrode, and the other one may be connected to the driving TFT. The driving TFT may include gate, source, and drain electrodes, and any one thereof may be connected to the semiconductor light-emitting element 1050 and another one may be connected to the Vss electrode. Furthermore, the other one may be connected to the switching TFT. In the case of the switching TFT, one of the gate, source, and drain electrodes may be connected to the driving TFT, and the remaining electrodes may be connected to the gate electrode Vgate and the data electrode Vdata, respectively. Meanwhile, a capacitor may be connected between the switching TFT and the driving TFT. The capacitor may be provided with a first pole and a second pole corresponding to an anode or a cathode, and for example, the first pole may be connected between the switching TFT and the driving TFT, and the second pole may be connected to the Vss electrode. The “connection” mentioned above refers to an electrical connection.

Meanwhile, the Vss electrode and the Vdd electrode are voltage supply sources to which a constant voltage is applied, and different voltages may be applied to the respective electrodes. For example, a ground voltage may be applied to the Vss electrode and a power supply voltage may be applied to the Vdd electrode. On the contrary, different voltages may be applied to the gate electrode Vgate and the data electrode Vdata according to time. The driving of the semiconductor light-emitting element 1050 may be controlled by voltages applied to the gate electrode Vgate and the data electrode Vdata.

The foregoing description may also be applied to FIGS. 10 and 11 related to an active matrix driving type display device in the related art. However, the above description is only one embodiment, and all active matrix driving type display devices are not limited to the structure described above.

Hereinafter, a display device having a new pixel region structure and a manufacturing method thereof according to the present disclosure will be described.

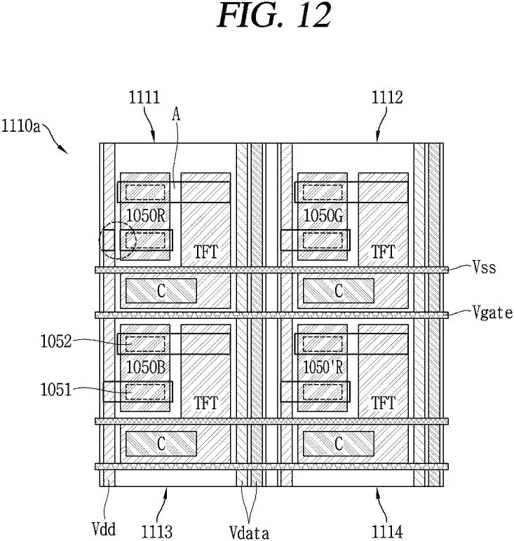

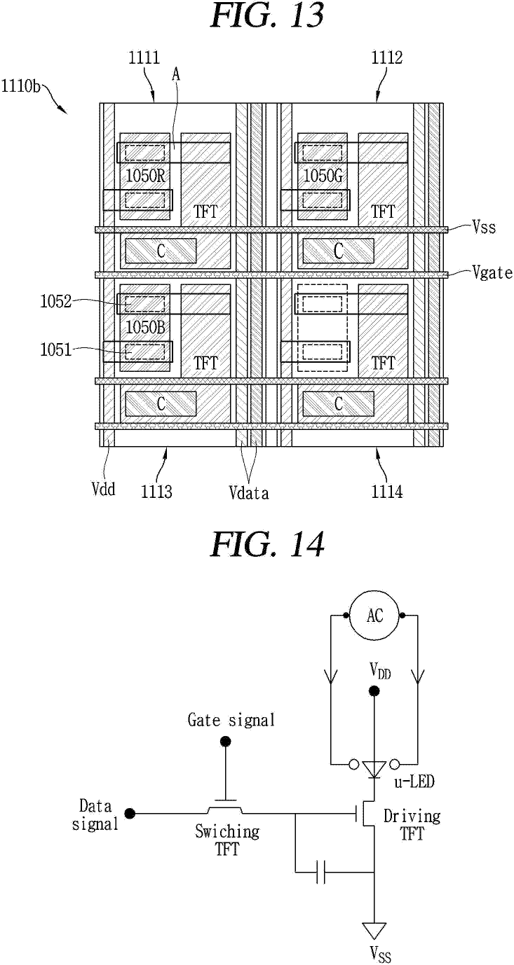

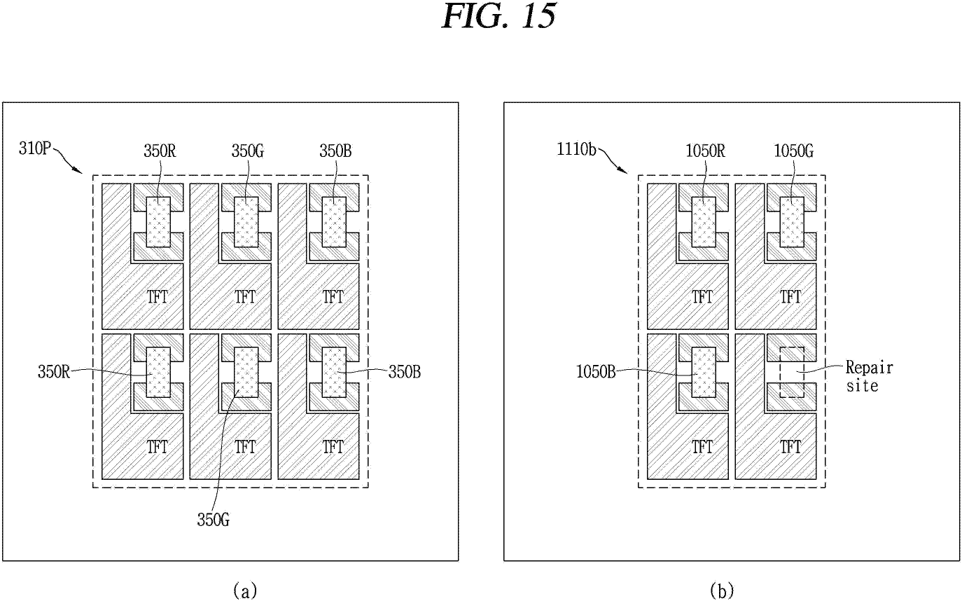

FIG. 12 is a view showing a pixel region (first pixel region) constituting a display device according to the present disclosure, FIG. 13 is a view showing a pixel region (second pixel region) constituting the display device according to the present disclosure, and FIG. 14 is a circuit diagram of a pixel region constituting the pixel region according to FIGS. 12 and 13.

According to the present disclosure, the display device 1000 may be disposed with wiring electrodes (Vss, Vdd, Vgate, Vdata), semiconductor light-emitting elements 1050, thin-film transistors (TFTs), and the like on the base portion. The base portion may be made of an insulating material or may be made of a material capable of implementing flexibility. Some of the wiring electrodes may be disposed on the same plane as the thin-film transistor, and the rest of the wiring electrodes may be disposed on another plane. In this case, an insulating layer may be disposed between the thin-film transistor TFT and the wiring electrode.

The base portion may include a plurality of pixel regions 1110. A plurality of semiconductor light-emitting elements 1050 and a plurality of thin-film transistors (TFTs) that drive the semiconductor light-emitting elements 1050 may be disposed in the pixel region 1110. In detail, the pixel region 1110 may include a first sub-pixel region 1111 in which a red semiconductor light-emitting element 1050R is disposed, a second sub-pixel region 1112 in which a green semiconductor light-emitting element 1050G is disposed, a third sub-pixel region 1113 in which a blue semiconductor light-emitting element 1050B is disposed, and a fourth sub-pixel region 1114 in which any one of red, green, and blue semiconductor light-emitting elements can be disposed.

According to the present disclosure, the pixel region 1110 may be designed with a quad structure including three sub-pixel regions in which semiconductor light-emitting elements constituting individual pixels are disposed, and one sub-pixel region in which a semiconductor light-emitting element for repair purposes is disposed. A semiconductor light-emitting element may be selectively disposed in the fourth sub-pixel region 1114, and a detailed description thereof will be described later.

In addition, thin-film transistors (TFTs) may be disposed in the first to fourth sub-pixel regions to drive the semiconductor light-emitting element disposed in each sub-pixel region.

According to the present disclosure, the pixel region 1110 is configured with the first to fourth sub-pixel regions 1111 to 1114, and the first to fourth sub-pixel regions 1111 to 1114 may be arranged in a plurality of rows and columns in the pixel region 1110. That is, the four sub-pixel regions constituting the pixel region 1110 may be arranged in 2 rows x 2 columns.

According to the present disclosure, the pixel region 1110 may include only the fourth sub-pixel region 1114, which is a region in which a redundant semiconductor light-emitting element 1050′ is disposed. The redundant semiconductor light-emitting element 1050′ may be selectively disposed in the fourth sub-pixel region 1114, and any one of red, green, and blue semiconductor light-emitting elements may be disposed therein.

Specifically, when a defective semiconductor light-emitting element is disposed in any one of the first to third sub-pixel regions 1111 to 1113 constituting the pixel region 1110, the semiconductor light-emitting element is disposed in the fourth sub-pixel region 1114. In this case, the semiconductor light-emitting element disposed in the fourth sub-pixel region 1114 may be a semiconductor light-emitting element emitting light of the same color as that of the defective semiconductor light-emitting element. On the contrary, when all of the semiconductor light-emitting elements disposed in the first to third sub-pixel regions 1111 to 1113 constituting the pixel region 1110 are normal, the semiconductor light-emitting element may not be disposed in the fourth sub-pixel region 1114. As described above, according to the present disclosure, only the semiconductor light-emitting element corresponding to the defective semiconductor light-emitting element in the pixel region 1110 may be additionally disposed, thereby saving a space occupied by the pixel region 1110.

According to the present disclosure, the plurality of pixel regions 1110 may be divided into pixel regions including the fourth sub-pixel region 1114 in which the semiconductor light-emitting element is disposed, and pixel regions including the fourth sub-pixel region 1114 in which the semiconductor light-emitting element is not disposed. Hereinafter, the pixel region including the fourth sub-pixel region 1114 in which the semiconductor light-emitting element is disposed is defined as a first pixel region 1110a, and the pixel including the fourth sub-pixel region 1114 in which the semiconductor light-emitting element is not disposed as a second pixel region 1110b.

Meanwhile, wire electrodes may be disposed on the base portion to pass through the pixel regions 1110. The wire electrodes may be disposed to pass through the plurality of pixel regions 1110 along an extension direction.

The wiring electrodes may include a gate electrode Vgate and a data electrode Vdata that control the lighting of the semiconductor light-emitting elements 1050. For example, the gate electrode Vgate may extend in a first direction (a row direction in the drawing), and the data electrode Vdata may extend in a second direction (a column direction in the drawing) crossing the first direction, and may be provided with a plurality of lines arranged at predetermined intervals. The gate electrode Vgate and the data electrode Vdata may be electrically connected to the thin-film transistor TFT disposed in the pixel region 1110.

According to the present disclosure, semiconductor light-emitting elements disposed on the same line along the first direction within the pixel region 1110 may share the gate electrode Vgate. That is, driving information for two semiconductor light-emitting elements may be allocated to the gate electrode Vgate. On the contrary, the semiconductor light-emitting elements 1050 constituting the pixel region 1110 may be electrically connected to different data electrodes Vdata, and driving information for one semiconductor light-emitting element may be allocated to the data electrode Vdata. That is, according to an embodiment of the present disclosure, the gate electrode Vgate may be a common electrode, and the data electrode Vdata may be an individual electrode.

In addition, the wiring electrodes may include a Vss electrode to which a ground voltage is applied and a Vdd electrode to which a power supply voltage is applied. The Vss electrode may be disposed in parallel to the gate electrode Vgate, and the Vdd electrode may be disposed in parallel to the data electrode Vdata. Furthermore, the Vss electrode may be electrically connected to the thin-film transistor TFT, and the Vdd electrode may be electrically connected to the semiconductor light-emitting element 1050.

On the other hand, referring to FIG. 12, in any one of the first to third sub-pixel regions 1111 to 1113 constituting the first pixel region 1110a, an electrical connection (A) between the semiconductor light-emitting element 1050 disposed in the sub-pixel region and the Vdd electrodes may be removed. This is the removal of the electrical connection between a defective semiconductor light-emitting element and the Vdd electrode, which may be performed through a laser lift-off (LLO) method, or the like, and a voltage signal applied to the defective semiconductor light-emitting element may be cut off by disconnecting the wiring. According to the present disclosure, since the defective semiconductor light-emitting element is not removed, the defective semiconductor light-emitting element remains in the final display device. Meanwhile, the electrical connection (A) shown in FIG. 12 indicates a connection relationship between components, and does not indicate a specific configuration for an electrical connection.

FIG. 15 is a view showing a pixel region of a display device in the related art and a pixel region of a display device according to the present disclosure. Referring to FIG. 15, according to the present disclosure, pixels may be designed in a quad structure to reduce an area occupied by a pixel region so as to decrease a gap between the pixels, thereby implementing high resolution. In addition, according to the present disclosure, a number of semiconductor light-emitting elements redundantly transferred to a display panel may be decreased, thereby reducing manufacturing cost.

Hereinafter, a method of manufacturing a display device according to the present disclosure will be described.

First, a step of forming wire electrodes (Vss, Vdd, Vgate, Vdata) and thin-film transistors (TFTs) on the base portion may be performed. In this step, the thin-film transistors (TFTs) may be disposed in the first to fourth sub-pixel regions 1111 to 1114 constituting the aforementioned pixel region 1110, respectively, and may be electrically connected the gate electrode Vgate and the data electrode Vdata. Furthermore, in this step, a capacitor C may be formed, and the capacitor C may be disposed to be electrically connected to the thin-film transistor TFT and the Vss electrode.

Next, a step of disposing semiconductor light-emitting elements 1050 at preset positions on the base portion may be performed. In this case, the preset position may refer to the pixel region 1110, and in detail, the first to third sub-pixel regions 1111 to 1113 constituting the pixel region 1110. In the present embodiment, since the fourth sub-pixel region 1114 among the first to fourth sub-pixel regions constituting the pixel region 1110 is a region in which a semiconductor light-emitting element for repair purposes is disposed, in this step, a semiconductor light-emitting element may not be disposed in the fourth sub-pixel region 1114.

The semiconductor light-emitting elements 1050 may be disposed to be electrically connected to the thin-film transistors (TFTs) and the specific data electrode Vdata disposed in the same sub-pixel region. The semiconductor light-emitting elements 1050 may be electrically connected to the thin-film transistors TFT and the data electrode Vdata in various ways, such as a conductive adhesive layer, a solder bump, or a connection electrode. Furthermore, while forming an electrical connection between the semiconductor light-emitting element 1050 and the thin-film transistor TFT, driving information for the semiconductor light-emitting element electrically connected thereto may be allocated to the thin-film transistor.

Next, a step of applying voltages to the wiring electrodes to check whether the semiconductor light-emitting element 1050 is defective may be performed. For example, voltages may be applied to the gate electrode Vgate and the data electrode Vdata to determine whether the semiconductor light-emitting element 1050 is defective, and the semiconductor light-emitting element that does not turn on when the voltages are applied thereto may correspond to a defective semiconductor light-emitting element 1050′. For example, this step may be performed for each region after dividing the base portion into a plurality of regions.

Next, a step of performing repair according to a result of checking whether or not it is defective may be performed. The step of performing of the repair may be a step of limiting the lighting of the semiconductor light-emitting element 1050′ identified as defective, and disposing a new semiconductor light-emitting element 1050 that replaces the defective semiconductor light-emitting element 1050′. The new semiconductor light-emitting element 1050 that replaces the defective semiconductor light-emitting element 1050′ may be disposed in the fourth sub-pixel region 1114 of the same pixel region 1110, and may be electrically connected to a thin-film transistor that has been previously disposed in the fourth sub-pixel region 1114. In addition, the new semiconductor light-emitting element 1050 may be provided with a semiconductor light-emitting element emitting light of the same color as the semiconductor light-emitting element 1050′ identified as defective in the same pixel region 1110. Meanwhile, when the pixel region 1110 does not include a defective semiconductor light-emitting element, the new semiconductor light-emitting element may not be disposed in the fourth sub-pixel region 1114.

That is, the display device according to the present disclosure may be divided into a first pixel region 1110a including a fourth sub-pixel region in which a semiconductor light-emitting element is disposed, and a second pixel region 1110b including a fourth sub-pixel region in which a semiconductor light-emitting element is not disposed.

Specifically, the step of performing repair may include disconnecting an electrical connection between the defective semiconductor light-emitting element 1050′ and the wire electrode (data electrode Vdata) (first step), disposing a new semiconductor light-emitting element 1050 at a preset position of the base portion, that is, in the fourth sub-pixel region 1114 (second step), and allocating driving information for the new semiconductor light-emitting element to a thin-film transistor (TFT) (third step). Here, the second step may also precede the first step.

According to the present disclosure, in the first step, the lighting of the defective semiconductor light-emitting element 1050′ may be limited by removing an electrical connection between the defective semiconductor light-emitting element 1050′ and the data electrode Vdata without removing the defective semiconductor light-emitting element 1050′, thereby preventing the thin-film transistor (TFT) from being damaged.

Meanwhile, in the case of the present disclosure, driving information for the semiconductor light-emitting element may be allocated to the thin-film transistor (TFT) disposed in the fourth sub-pixel region 1114 of the first pixel region 1110a in a repair process.

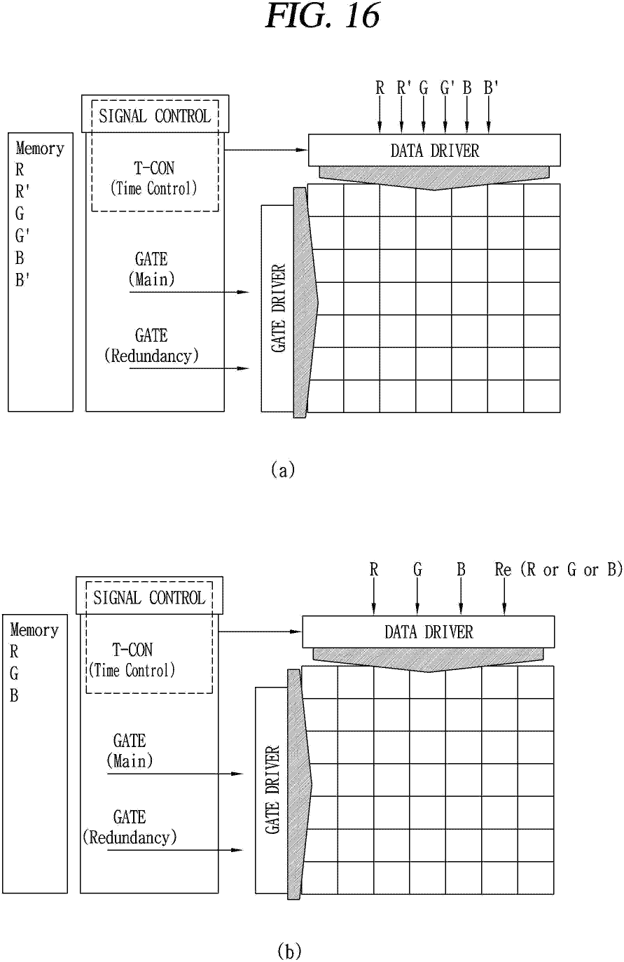

FIG. 16 is a view showing a signal configuration of a display device in the related art and a signal configuration of a display device according to the present disclosure. Referring to FIG. 16, in the case of a display device in the related art, redundant semiconductor light-emitting elements may be transferred for individual pixels, and thin-film transistors may be matched one-to-one to semiconductor light-emitting elements within one pixel region, and thus driving information for the semiconductor light-emitting elements may be allocated in advance to respective thin-film transistors. However, according to the present disclosure, after a lighting test is carried out on semiconductor light-emitting elements disposed in the first to third sub-pixel regions, a semiconductor light-emitting element to be disposed in the fourth sub-pixel region may be determined according to the result, and thus driving information for the semiconductor light-emitting element may be allocated to a thin-film transistor disposed in the fourth sub-pixel region in a repair process. Meanwhile, in the case of the second pixel region 1110b, the fourth sub-pixel region 1114 may not include a semiconductor light-emitting element, and thus driving information for the semiconductor light-emitting element may not be allocated to the thin-film transistor (TFT) disposed in the fourth sub-pixel region 1114.

The present disclosure described above will not be limited to configurations and methods according to the above-described embodiments, and all or part of each embodiment may be selectively combined and configured to make various modifications thereto.

1. A display device comprising:
a base portion comprising a plurality of pixel regions;
a plurality of semiconductor light-emitting elements disposed in the plurality of pixel regions; and
a plurality of thin-film transistors disposed in the plurality of pixel regions to drive the semiconductor light-emitting elements,
wherein the plurality of pixel regions comprise a first sub-pixel region in which a red semiconductor light-emitting element is disposed, a second sub-pixel region in which a green semiconductor light-emitting element is disposed, a third sub-pixel region in which a blue semiconductor light-emitting element is disposed, and a fourth sub-pixel region in which any one of red, green and blue light-emitting elements can be disposed, and
wherein the thin-film transistors are disposed in the first to fourth sub-pixel regions, respectively.

2. The display device of claim 1, wherein the first to fourth sub-pixel regions are arranged in a plurality of rows and columns in the plurality of pixel regions.

3. The display device of claim 2, wherein the plurality of pixel regions comprise:
a first pixel region comprising the fourth sub-pixel region in which the semiconductor light-emitting elements are disposed; and
a second pixel region comprising the fourth sub-pixel region in which the semiconductor light-emitting elements are not disposed.

4. The display device of claim 3, further comprising:
a wiring electrode disposed to pass through the plurality of pixel regions;
wherein the wiring electrode comprises:
a gate electrode extending in a first direction; and
a data electrode extending in a second direction crossing the first direction, and
wherein the gate electrode and the data electrode are electrically connected to the thin-film transistors.

5. The display device of claim 4, wherein the wiring electrode comprises:
a Vss electrode disposed in parallel to the gate electrode, to which a ground voltage is applied; and
a Vdd electrode disposed in parallel to the data electrode, to which a power supply voltage is applied, and
wherein the Vss electrode is electrically connected to the thin-film transistors, and the Vdd electrode is electrically connected to the semiconductor light-emitting elements.

6. The display device of claim 5, wherein an electrical connection between the semiconductor light-emitting elements and the Vdd electrode is removed from any one of the first to third sub-pixel regions of the second pixel region.

7. A method of manufacturing a display device, the method comprising:
forming wiring electrodes and thin-film transistors on a base portion;
disposing semiconductor light-emitting elements at preset positions on the base portion so as to be electrically connected to the wiring electrodes and the thin-film transistors;
applying voltages to the wiring electrodes to check whether the semiconductor light-emitting elements are defective; and
performing repair according to a result of checking whether the semiconductor light-emitting elements are defective,
wherein the performing of the repair comprises limiting the lighting of the semiconductor light-emitting elements identified as defective, and disposing new semiconductor light-emitting elements that replace the semiconductor light-emitting elements identified as defective.

8. The method of claim 7, wherein the performing of the repair comprises:
disconnecting an electrical connection between the semiconductor light-emitting elements identified as defective and the wiring electrode;
disposing the new semiconductor light-emitting element elements at a preset position of the base portion; and
allocating driving information for the new semiconductor light-emitting elements to the thin-film transistors.

9. The method of claim 8, wherein the base portion comprises a plurality of pixel regions,
wherein the plurality of pixel regions comprise a first sub-pixel region in which a red semiconductor light-emitting element is disposed, a second sub-pixel region in which a green semiconductor light-emitting element is disposed, a third sub-pixel region in which a blue semiconductor light-emitting element is disposed, and a fourth sub-pixel region in which any one of red, green and blue light-emitting elements can be disposed, and
wherein the thin-film transistors are disposed in the first to fourth sub-pixel regions, respectively.

10. The method of claim 9, wherein the performing of the repair is performed for each of the plurality of pixel regions, and
wherein the new semiconductor light-emitting elements are disposed in the fourth sub-pixel region, and provided with a semiconductor light-emitting element emitting light of the same color as the semiconductor light-emitting elements identified as defective in the plurality of pixel regions.

11. The method of claim 9, wherein the first to fourth sub-pixel regions are arranged in a plurality of rows and columns in the plurality of pixel regions.

12. The method of claim 9, wherein the plurality of pixel regions comprise:
a first pixel region comprising a fourth sub-pixel region in which the semiconductor light-emitting elements are disposed; and
a second pixel region comprising a fourth sub-pixel region in which the semiconductor light-emitting elements are not disposed.

13. The method of claim 12, wherein driving information for a semiconductor light-emitting element is not allocated to a thin-film transistor disposed in the fourth sub-pixel region of the second pixel region.
